(19) United States
(12) Patent Application Publication
(10) Pub. No.: US 2021/0305080 A1
(43) Pub. Date: Sep. 30, 2021

(54) WAFER SURFACE PROCESSING DEVICE

(71) Applicant: Hunan Sanan Semiconductor Co., Ltd., Hunan (CN)

(72) Inventors: JIE ZHANG, Hunan (CN); SHUANGTU SU, Hunan (CN); WUQING LIN, Hunan (CN); ZELONG WANG, Hunan (CN)

(21) Appl. No.: 17/205,514

(22) Filed: Mar. 18, 2021

(30) Foreign Application Priority Data
Mar. 25, 2020 (CN) 202010220765.1A

(51) Int. Cl. H01L 21/683; H01L 21/67; B24B 41/06

(52) U.S. Cl. CPC H01L 21/6838; B24B 41/06; H01L 21/67259

(57) ABSTRACT

A detachable etching tool for etching a plurality of silicon carbide pieces has a first supporting column and a second supporting column, both of which are fixed through a tool fixing block. A bracket is arranged on the tool fixing block, and a limiting rod is installed on the lower end surface of the bracket. The bracket is inserted into the tool fixing block through the limiting rod and fixed on the tool fixing block with a fastening mechanism that comprises a base, a fixing seat, a telescopic spring, a telescopic guide column, a sliding block, a guide block, an inserting rod and a push-pull mechanism. The etching tool addresses low productivity per unit time and reduced speed in wafer etching processing.

### CROSS-REFERENCE TO RELATED APPLICATIONS

This application claims priority to Chinese Utility Patent Application No. 202010220765.1A entitled “WAFER SURFACE PROCESSING DEVICE” filed before China's National Intellectual Property Administration on Mar. 25, 2020, the entire contents of each of which are incorporated herein by reference.

### STATEMENT RE: FEDERALLY SPONSORED RESEARCH/DEVELOPMENT

Not Applicable

### BACKGROUND

### 1. Technical Field

The present disclosure relates to the field of semiconductor single crystal material processing, and in particular to a wafer surface processing device.

### 2. Related Art

As a third generation semiconductor material, silicon carbide (SiC) has become the key semiconductor material of the new generation of microelectronic devices and circuits because of its superior properties of wide band gap, high breakdown field, large thermal conductivity, high electron saturation drift speed, strong radiation resistance and good chemical stability. Silicon carbide is matched well with gallium nitride (GaN), which is an important material for making high-power microwave, power electronics and optoelectronic devices, and making silicon carbide an important substrate material for the new generation of broadband semiconductor devices. It is expected to be applied to energy conservation and emission reduction, information technology and national defense, which will give birth to a lucrative potential market and become one of the directions of new energy development in the future.

However, silicon carbide, as an epitaxial substrate material, surface profiles are an important requirement necessitating a series of specific processing techniques. The control of SiC wafer profile is essential to SiC processing to limit warpage, bow and thickness difference (TTV) of SiC wafer, otherwise epitaxial quality will be affected.

The traditional method of processing wafers uses double-sided grinding to repair the cut wafer profile, which has great limitations, mainly limited by the cut wafer surface profile. If the cut wafer profile is not within the specifications of double-sided grinding repair, the upper and lower surfaces of the wafer will be squeezed during double-sided grinding, resulting in deformation of the wafer. However, after processing, the wafer returns to its original shape, resulting in its original profile structure being maintained, resulting in a high degree of wafer warpage.

### SUMMARY

The purpose of the present disclosure is to provide a wafer surface processing device to alleviate the technical problem that the existing wafer surface flatness repair effect is poor after wafer processing.

One embodiment of the invention provides a wafer surface processing device which comprises a grinding mechanism, a first fixing mechanism and a second fixing mechanism, wherein the grinding mechanism comprises a grinding disc. The first fixing mechanism may comprise a fixing groove, and the bottom surface of the fixing groove may be provided with an accommodating groove for accommodating a connecting medium solution. The fixing groove and the accommodating groove may form a stepped structure for supporting a first surface of a wafer. A second fixing mechanism may be used for connecting with the processed second surface of the wafer, so that the grinding disc can grind the first surface of the wafer. Further, the wafer surface processing device may further comprise a first vacuum chuck and a lifting driving mechanism, wherein the lifting driving mechanism is used for driving the first vacuum chuck to move towards or away from the fixing groove, and the first vacuum chuck may be used for grasping the wafer and transferring the wafer to the first fixing mechanism.

Further, the first vacuum chuck may be provided with a pressure sensor for sensing the pressure of the first vacuum chuck from the first fixing mechanism, and the pressure sensor is connected with the lifting driving mechanism, so that the lifting driving mechanism stops moving when the pressure sensor reaches a preset value.

Further, the number of fixing grooves on the first fixing mechanism may be multiple.

Further, the first vacuum chuck may be provided with a distance sensor for sensing the distance between the adsorption surface of the first vacuum chuck and the stepped surface of the stepped structure, and the distance sensor is connected with the lifting driving mechanism so that the lifting driving mechanism stops moving when the distance sensor reaches a preset value.

Further, the first fixing mechanism may comprise a heating device, and the heating device may be used for heating the accommodating groove.

Further, the first fixing mechanism may comprise a rotation driving mechanism and a fixing plate, the fixing groove may be located on the fixing plate, the rotation driving mechanism may be connected with the fixing plate, and the rotation driving mechanism may be used for driving the fixing plate to rotate, so that the second surface of the wafer rubs against rotation on the grinding plate.

Further, the first fixing mechanism may comprise a radial driving mechanism, which is connected with the fixed disk and used for driving the fixed disk to move along the radial direction of the grinding disk.

Furthermore, the number of the grinding mechanisms may be multiple, and the roughness of grinding discs on the multiple grinding mechanisms may be different.

Further, the second fixing mechanism may comprise a second vacuum chuck which can move towards or away from the grinding disc.

The wafer surface processing device provided by an embodiment of the disclosure comprises a grinding mechanism, a first fixing mechanism and a second fixing mechanism, wherein the grinding mechanism comprises a grinding disc for grinding a first surface and a second surface of a wafer in sequence. The first fixing mechanism may comprise a fixing groove, and the bottom surface of the fixing groove may be provided with an accommodating groove for accommodating a connecting medium solution. The fixing groove and the accommodating groove may form a stepped structure. Firstly, the connecting medium solution may be injected into the accommodating groove, and then the wafer may be placed on the fixing groove. The stepped structure may supports the first surface of the wafer. After the connecting medium solution is solidified, the wafer can be fixedly connected in the fixing groove. After the second surface is polished, the second fixing mechanism may be used to connect with the processed second surface of the wafer, and then the first surface of the wafer may be polished by the polishing disk, so that both the first surface and the second surface can be polished smoothly. The first surface and the second surface of the wafer polished successively by the device can be polished flat. The wafer can be polished twice by using the device, and in the polishing process, the wafer is not deformed by extrusion, and only the first surface and the second surface are simply polished flat, so that the finished wafer is flat in surface shape, and the problem of curling caused by deformation of the wafer caused by extrusion and recovery of deformation after polishing in the double-sided polishing mode in the prior art is avoided.

### BRIEF DESCRIPTION OF THE DRAWINGS

In order to explain the specific embodiment of the present invention or the technical scheme in the prior art more clearly, the drawings used in the description of the specific embodiment or the prior art will be briefly introduced below. Obviously, the drawings in the following description are some embodiments of the present invention, and other drawings can be obtained according to these drawings for ordinary technicians in the field without paying creative labor.

FIG. 1 is a top plan view of a fixing plate of a wafer surface processing device provided by an embodiment of the present disclosure;

FIG. 2 is a cross sectional view taken along A-A direction in FIG. 1;

FIG. 3 is a side view of fixing a wafer to a fixing plate in a wafer surface type processing device provided by an embodiment of the present disclosure;

FIG. 4 is a side view of polishing the second surface of a wafer in the wafer surface processing device provided by an embodiment of the present disclosure;

FIG. 5 is a side view of polishing a first surface of a wafer in a wafer surface processing device provided by an embodiment of the present disclosure.

### DETAILED DESCRIPTION

In the following, the technical scheme of the present invention will be clearly and completely described with examples. The described examples are part of the embodiments of the present disclosure, not all of them. Based on the embodiments of the present disclosure, all other embodiments obtained by ordinary technicians in the field without creative labor belong to the scope of protection of the present disclosure.

Reference Numbers: 100—Grinding plate; 200—fixed plate; 210—fixed groove; 220—containing groove; 310—First vacuum chuck; 320—pressure sensor; 330—distance sensor; 400—heating device; 500—Rotary drive mechanism; 600—second vacuum chuck.

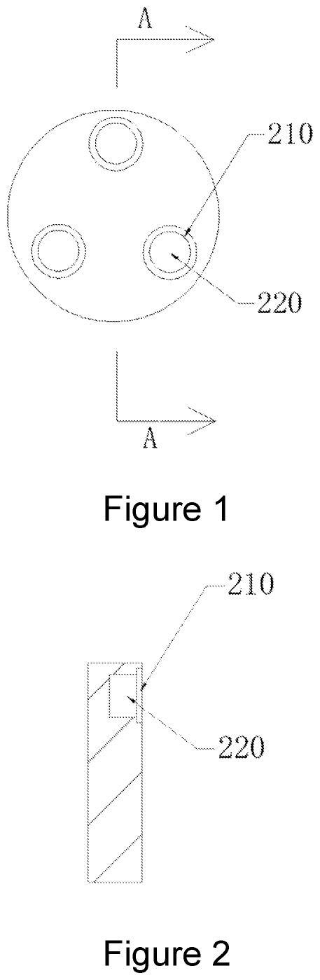

As shown in FIG. 1-5, the wafer surface processing device provided by the embodiment of the present disclosure comprises a grinding mechanism, a first fixing mechanism and a second fixing mechanism, wherein the grinding mechanism comprises a grinding disc 100 for grinding the first surface and the second surface of the wafer in sequence. The first fixing mechanism comprises a fixing groove 210, the bottom surface of which is provided with an accommodating groove 220 for accommodating a connecting medium solution, and the fixing groove 210 and the accommodating groove 220 form a stepped structure, wherein the connecting medium solution is injected into the accommodating groove 220 first, and then the wafer is placed on the fixing groove 210, and the stepped structure supports the first surface of the wafer. The wafer can be fixedly connected in the fixing groove 210, and the second surface of the wafer is exposed outside the fixing groove 210, so that the polishing disk 100 can polish the second surface of the wafer and polish it flat. After the second surface is polished, the second fixing mechanism is used to connect with the processed second surface of the wafer, and then the first surface of the wafer is polished by the polishing plate 100, so that both the first surface and the second surface can be polished flat. The first surface and the second surface of the wafer polished successively by the device can be polished flat.

The first side of the wafer is fixed by using a connecting medium solution, and the second side can be polished into a plane parallel to the first fixing mechanism. Then, the flat second side is connected by using the second fixing mechanism, and the first side can also be polished into a flat plane after polishing. The wafer is polished twice by using the device, and in the polishing process, the wafer is not deformed by extrusion, and only the first surface and the second surface are simply polished flat, so that the finished wafer is flat in surface shape, and the problem of curling caused by deformation of the wafer caused by extrusion and recovery of deformation after polishing in the prior art is avoided.

The grinding mechanism also includes a rotating shaft, which drives the grinding disc 100 to rotate, and a DIA grinding pad with rough surface is attached to the grinding disc 100.

The connecting medium solution used in this embodiment can be liquid wax, but is not limited to liquid wax. All the medium melted by heating and solidified at normal temperature can be used as connecting wafer, which is within the scope of protection.

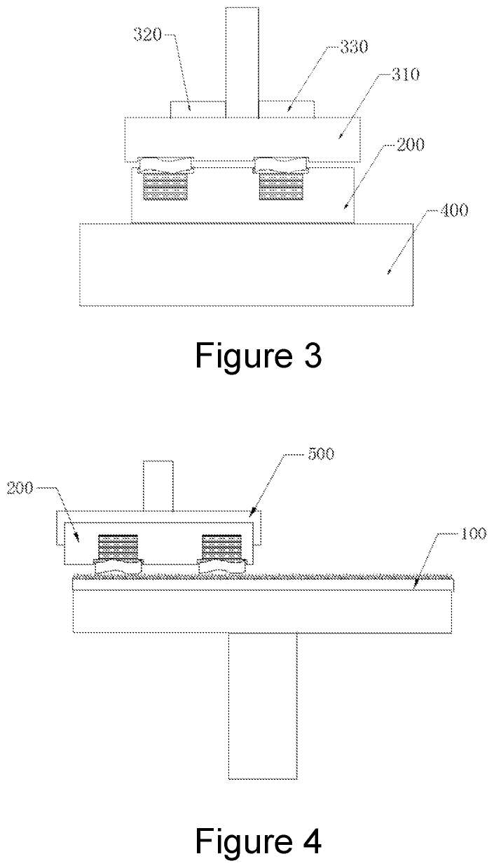

As shown in FIG. 3, the wafer surface processing device includes a first vacuum chuck 310 and a lifting driving mechanism for driving the first vacuum chuck 310 to move toward or away from the fixing groove 210, and the first vacuum chuck 310 is used for grasping the wafer and transferring the wafer to the first fixing mechanism.

The wafer can be transported by the first vacuum chuck 310 mechanism, and the wafer to be processed is sucked by the first vacuum chuck 310, and then transferred to the upper part of the fixing groove 210, and then the first vacuum chuck 310 descends to drop the wafer into the fixing groove 210.

The first vacuum chuck 310 is provided with a pressure sensor 320 for sensing the pressure of the first vacuum chuck 310 from the first fixing mechanism, and the pressure sensor 320 is connected with the lifting driving mechanism so that the lifting driving mechanism stops moving when the pressure sensor 320 reaches a preset value.

The first vacuum chuck 310 moves from top to bottom. As the wafer on the first vacuum chuck 310 comes into contact with the fixing groove 210, the pressure sensed by the pressure sensor 320 will gradually increase. When the pressure reaches a preset value, it will stop falling. On the one hand, it can prevent the wafer from being excessively squeezed and deformed, and on the other hand, it can make the wafer bear a certain pressure, thus preventing the wafer from stepping relative to the ladder structure due to the connection of medium solution.

In order to increase the processing efficiency, the number of fixing grooves 210 on the first fixing mechanism is multiple. In this embodiment, the number of fixing grooves 210 is three.

The first vacuum chuck 310 is provided with a distance sensor 330 for sensing the distance between the suction surface of the first vacuum chuck and the stepped surface of the stepped structure, and the distance sensor 330 is connected with the lifting driving mechanism so that the lifting driving mechanism stops moving when the distance sensor 330 reaches a preset value.

The initial thicknesses of wafers to be processed are different. By setting the descending distance of the first vacuum chuck 310, the highest points of all wafers on the same first vacuum chuck 310 can be kept on the same plane, which can prevent some wafers with larger thickness from being squeezed and deformed, and can ensure that the original surface shape of wafers is not changed.

The first fixing mechanism includes a heating device 400 for heating the accommodating groove 220. After heating by the heating device 400, the connecting medium solution can be kept in a liquid state, so as to avoid solidification when the wafer is not placed in the fixing tank 210. At the same time, the wafer can be separated conveniently by heating the cured wax.

As shown in FIG. 4, the first fixing mechanism includes a rotation driving mechanism 500 and a fixing plate 200, the fixing groove 210 is located on the fixing plate 200, the rotation driving mechanism 500 is connected with the fixing plate 200, and the rotation driving mechanism 500 is used to drive the fixing plate 200 to rotate, so that the second surface of the wafer rubs against rotation on the grinding plate 100.

The material of the fixing plate 200 can be ceramic, the fixing groove 210 and the accommodating groove 220 form a stepped structure, and the movable end of the rotation driving mechanism 500 is connected with the fixing plate 200. In this embodiment, the movable end of the rotation driving mechanism 500 can be clamped with the fixing plate 200, so that they are connected together. The grinding disc 100 rotates, while the fixed disc 200 rotates under the driving of the rotation driving mechanism 500. The grinding disc 100 and the fixed disc 200 are in an unacceptable rotation state, so that the second side of the wafer can be polished by the grinding disc 100.

The first fixing mechanism comprises a radial driving mechanism, which is connected with the fixed disk 200 and used for driving the fixed disk 200 to move along the radial direction of the grinding disk 100.

In this embodiment, the radial driving mechanism can be a linear sliding module, the movable end of which is connected with the rotary driving mechanism 500, and the radial driving mechanism can drive the rotary driving mechanism 500 and the fixed disk 200 to reciprocate along the radial direction of the polishing disk 100, so that the second surface of the wafer can be polished more evenly, and the problem that the wafer is thick in the middle and thin in the edge after polishing is avoided, so that the wafer surface is very flat after polishing.

There are a plurality of grinding mechanisms, and the roughness of the grinding discs 100 on the plurality of grinding mechanisms is different.

In the polishing process, a polishing mechanism with lower roughness can be used to rough polish the surface of the wafer, and then a polishing mechanism with higher roughness can be used to fine polish the surface of the wafer, thus obtaining ultra-flat, ultra-smooth and low roughness wafers.

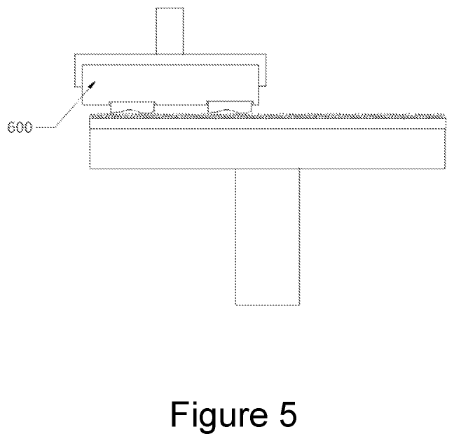

As shown in FIG. 5, the second fixing mechanism may include a second vacuum chuck 600 that can move toward or away from the grinding disc 100. The second vacuum chuck 600 can absorb the smooth second surface, and then the first surface of the wafer is polished by the polishing mechanism. Meanwhile, the second vacuum chuck 600 can drive the wafer to rotate and move along the radial direction of the grinding disc 100.

The present disclosure provides a device for improving that surface shape of a silicon carbide wafer, which grinds one surface of the SiC wafer on the basis of keep the original shape of the SiC wafer, and then adsorbs the grinded surface on an ultra-flat vacuum chuck to repair the other surface of the SiC wafer, thereby finally obtaining the ultra-flat SiC wafer.

The use method of the wafer processing device provided by the embodiment of the invention is as follows:

1. Place the fixed plate 200 on the heating mechanism for heating.

2. Fill the fixing groove 210 on the heated fixing plate 200 with the connecting medium solution.

3. Adsorb the wafer in the concave hole of the first vacuum chuck 310. When the first vacuum chuck 310 descends to a specified pressure or distance, the first vacuum chuck 310 will not descend. At this time, the heating mechanism does not heat, so that the connecting medium solution is cured without changing the original surface shape of the wafer, and the first surface of the wafer is stuck to the fixed plate 200.

4. Fix the wafer-adhered fixing plate 200 to the first fixing mechanism.

5. Set the rotating speed of the rotary drive mechanism 500, the reciprocating range of the radial drive mechanism and the rotating speed of the grinding disc 100.

6. Start the device to make the wafer fixing plate 200 and grinding plate 100 rotate relatively, so as to roughly grind the second side of the wafer, so as to obtain an ultra-flat wafer after grinding.

7. Then, transfer the fixed disk 200, which has been roughly ground and adhered to the wafer, to another grinding mechanism with high roughness for fine grinding, so as to obtain an ultra-flat, ultra-smooth and low-roughness SiC wafer after grinding.

8. After grinding one side, heat the fixed plate 200 with the wafer adhered to it, take it down and remove the wax and clean the wafer.

9. Adsorb the cleaned ultra-flat second surface of the wafer to the second vacuum chuck 600 to ensure that the vacuum suction will not cause the wafer to slip on the grinding stone.

10. rough machining and fine machining are carried out on the unprocessed side in the same way as above, so as to obtain SiC wafers with ultra-smooth and low roughness on both sides.

Starting from actual production, a new type of processing device for improving wafer surface profile has brought huge product benefits to actual production and wafer quality. The following table shows the data comparison between the traditional double-sided grinding method and the new device for improving the surface profile of silicon carbide wafer after grinding.

| | | | | raw | Pollution |
|---|---|---|---|---|---|
| Classification | Warp | Bow | TTV | materials | category |
| Traditional | 7-15 | 1-7 | 0.5-2 | DIA | chemical |
| double- | | | | grinding | pollution |
| sided | | | | fluid | |
| grinding | | | | | |
| method | | | | | |
| New | 15-60 | 6-15 | 1-4 | Consolidate | pollution- |
| device | | | | DIA | free |
| | | | | grinding | |
| | | | | pad and | |
| | | | | pure water | |

It can be seen from the above table that, compared with the traditional double-sided grinding method, the wafer surface processing device provided by the embodiment of the present invention has an overall warp reduction of 15-25 um, and the uniformity of warp is more concentrated; Bow decreased by 5-7 um and TTV decreased by 2-3 um as a whole. From the perspective of environmental protection, the device provided by the embodiment of the present invention is purely physically polished, and does not need to use DIA grinding fluid, thus achieving a better environmental protection effect.

The device provided by the embodiment of the invention can process various wafers, such as sapphire, monocrystalline silicon, silicon carbide and the like.

Finally, it should be noted that the above embodiments are only used to illustrate the technical scheme of the present invention, but not to limit it. Although the present invention has been described in detail with reference to the foregoing embodiments, those of ordinary skill in the art should understand that the technical solutions described in the foregoing embodiments can still be modified, or some or all of the technical features can be equivalently replaced; However, these modifications or substitutions do not make the essence of the corresponding technical solutions deviate from the scope of the technical solutions of each embodiment of the present invention.

What is claimed is:

1. A wafer surface processing device, comprising:
a griding mechanism comprising a grinding disc;
a first fixing mechanism including a fixing groove and an accommodating groove arranged on a bottom surface of the fixing groove, the fixing groove and the accommodating groove being used for accommodating a connecting medium solution and defining a stepped structure for supporting a first surface of a wafer; and
a second fixing mechanism for connecting with a processed second surface of the wafer, the grinding disc being configured to grind the first surface of the wafer.

2. The wafer surface processing device of claim 1, further comprising:
a first vacuum chuck; and
a lifting driving mechanism used for driving the first vacuum chuck to move towards or away from the fixing groove, and for grabbing the wafer and transferring the wafer to the first fixing mechanism.

3. The wafer surface processing device of claim 2, wherein the first vacuum chuck includes a pressure sensor for sensing the pressure of the first vacuum chuck from the first fixing mechanism, the pressure sensor being connected with the lifting driving mechanism.

4. The wafer processing device of claim 3, wherein the number of fixing grooves on the first fixing mechanism is plural.

5. The wafer surface processing device according to claim 4, wherein the first vacuum chuck is provided with a distance sensor for sensing the distance between the adsorption surface of the first vacuum chuck and the stepped surface of the stepped structure, the distance sensor being connected with the lifting driving mechanism.

6. The wafer processing device of claim 2, wherein the number of fixing grooves on the first fixing mechanism is plural.

7. The wafer surface processing device according to claim 6, wherein the first vacuum chuck is provided with a distance sensor for sensing the distance between the adsorption surface of the first vacuum chuck and the stepped surface of the stepped structure, the distance sensor being connected with the lifting driving mechanism.

8. The wafer surface processing device of claim 1, wherein the first fixing mechanism comprises a heating device for heating the accommodating groove.

9. The wafer surface processing device of claim 1, wherein the first fixing mechanism comprises a rotary driving mechanism and a fixing plate, the fixing groove being located on the fixing plate, and the rotary driving mechanism being connected with the fixing plate.

10. The wafer surface processing device of claim 1, wherein the first fixing mechanism comprises a radial driving mechanism, and the radial driving mechanism is connected with the fixed disk for driving the fixed disk to move along the radial direction of the grinding disk.

11. The wafer surface processing device of claim 1, wherein the number of the grinding mechanisms is multiple, and roughness of the grinding discs on the multiple grinding mechanisms is different.

12. The wafer surface type processing device of claim 1, wherein the second fixing mechanism comprises a second vacuum chuck that moves towards or away from the grinding disc.
